(19) United States
(12) Patent Application Publication
(10) Pub. No.: US 2016/0118433 A1
(43) Pub. Date: Apr. 28, 2016

(54) SEMICONDUCTOR FABRICATION METHOD

(71) Applicant: Powerchip Technology Corporation, Hsinchu (TW)

(72) Inventors: Tse-Wei Chung, Taichung City (TW); Tsung-Hui Chou, New Taipei City (TW); Yu-Yuan Lai, Miaoli County (TW)

(21) Appl. No.: 14/572,687

(22) Filed: Dec. 16, 2014

(30) Foreign Application Priority Data
Oct. 24, 2014 (TW) 103136845

(51) Int. Cl. H01L 27/146

(52) U.S. Cl. CPC H01L 27/14685; H01L 27/14689

(57) ABSTRACT

A semiconductor fabrication method is disclosed. A substrate having thereon a plurality of semiconductor elements are provided. A dielectric layer is formed on the substrate. A plurality of openings is etched into the dielectric layer to respectively reveal the semiconductor elements. A material layer is coated on the substrate and the material layer fills into the openings. The material layer is then subjected to exposure and development processes to remove a portion of the material layer, thereby forming a material pattern. The material pattern is then polished by chemical mechanical polishing.

### CROSS REFERENCE TO RELATED APPLICATION

This application claims the benefit of Taiwan patent application No. 103136845, filed on Oct. 24, 2014, the disclosure of which is incorporated herein in its entirety by reference.

### BACKGROUND OF THE INVENTION

1. Field of the Invention

The present invention relates to a semiconductor fabrication method and, more particularly, to a back-end-of-line (BEOL) method for fabricating CMOS image sensors.

2. Description of the Prior Art

As the development of electronic products such as digital cameras and scanners progresses, the demand for image sensors increases accordingly. In general, image sensors in common usage nowadays are divided into two main categories: charge coupled device (CCD) sensors and CMOS image sensors (CIS). Primarily, CMOS image sensors have certain advantages of low operating voltage, low power consumption, and an ability for random access. Furthermore, CMOS image sensors are currently capable of integration with the semiconductor fabrication process. Based on those benefits, the application of CMOS image sensors has increased significantly.

The CMOS image sensor separates incident light into a combination of light of different wavelengths. For example, the CMOS image sensor can consider incident light as a combination of red, blue, and green light. The light of different wavelengths is received by respective optically sensitive elements such as photodiodes and is subsequently transformed into digital signals of different intensities. Thus, it can be seen that a monochromatic color filter array (CFA) must be set above every optical sensor element for separating the incident light.

As the resolution of a CMOS image sensor increases, the size of each pixel sensor in the image sensor shrinks, which may also lead to the decreasing of the size of the photosensitive element (e.g., photodiode) in each pixel sensor. As the CMOS image sensors become increasingly more sophisticated, the pixel crosstalk increases. This becomes problematic when high sensitivity is required.

One of the methods to improve light sensitivity of the pixel sensor is to implement a light pipe on top of the photodiode. Such light pipe is fabricated in the BEOL (back end of line) phases. Typically, lightpipe openings are formed on the photodiode regions in the pixel array. A sping-coating material having a high refractive index is then formed on the substrate by spin-coating methods. The lightpipe openings are filled with the sping-coating material. The sping-coating material is then subjected to curing or baking. Subsequently, a color filter array layer and a microlens layer are formed on the substrate.

However, conventional lightpipe fabrication processes often lead to depth fluctuations and thickness variations for the lightpipes in the CMOS sensor. Therefore, there is still a need in this industry to provide an improved method for fabricating the CMOS sensor in order to solve the above-mentioned shortcomings.

### SUMMARY OF THE INVENTION

An improved semiconductor fabrication method is disclosed to achieve the invention purposes. According to one embodiment, a substrate having thereon a plurality of semiconductor elements are provided. A dielectric layer is formed on the substrate. A plurality of openings is etched into the dielectric layer to respectively reveal the semiconductor elements. A material layer is coated on the substrate and the material layer fills into the openings. The material layer is then subjected to exposure and development processes to remove a portion of the material layer, thereby forming a material pattern. The material pattern is then polished by chemical mechanical polishing.

The semiconductor substrate comprises a silicon substrate. The semiconductor elements comprise a photo-sensing element such as a photodiode.

According to one embodiment, the material layer is a photosensitive polymeric material having a high refractive index (n=1.7˜1.9) and a low extinction coefficient (k˜0) in the visible light range.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 to FIG. 4 are schematic, cross-sectional diagrams showing an exemplary semiconductor fabrication method according to one embodiment of the invention.

FIG. 5 illustrates another embodiment of the invention.

### DETAILED DESCRIPTION

In the following detailed description of the invention, reference is made to the accompanying drawings which form a part hereof, and in which is shown, by way of illustration, specific embodiments in which the invention may be practiced. These embodiments are described in sufficient detail to enable those skilled in the art to practice the invention. Other embodiments may be utilized and structural, logical, and electrical changes may be made without departing from the scope of the present invention. The following detailed description is, therefore, not to be taken in a limiting sense, and the scope of the present invention is defined by the appended claims.

The terms wafer and substrate used herein include any structure having an exposed surface onto which a layer is deposited according to the present invention, for example, to form the integrated circuit (IC) structure. The term substrate is understood to include semiconductor wafers. The term substrate is also used to refer to semiconductor structures during processing, and may include other layers that have been fabricated thereupon. Both wafer and substrate include doped and undoped semiconductors, epitaxial semiconductor layers supported by a base semiconductor or insulator, as well as other semiconductor structures well known to one skilled in the art.

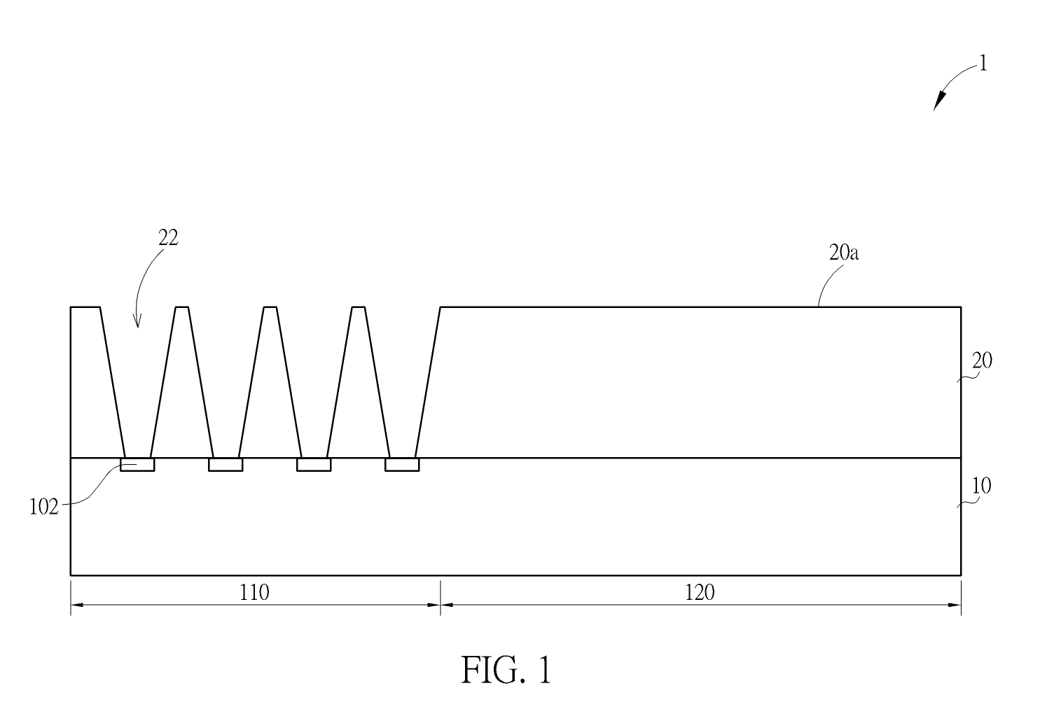

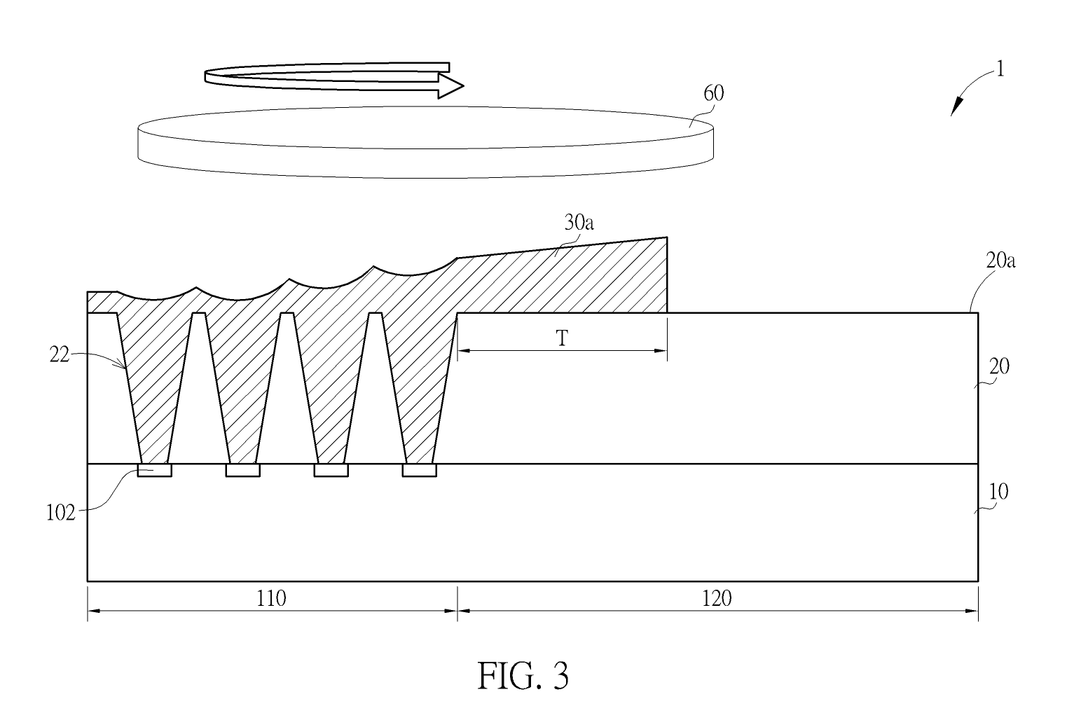

Please refer to FIG. 1 to FIG. 4. FIG. 1 to FIG. 4 are schematic, cross-sectional diagrams showing an exemplary semiconductor fabrication method according to one embodiment of the invention. The exemplary semiconductor fabrication method is particularly suited for the back end of line (BEOL) of a CMOS image sensor 1, but is not limited thereto.

First, as shown in FIG. 1, a semiconductor substrate 10 is provided. A plurality of semiconductor elements 102, for example, photo-sensing elements, may be formed on or in the semiconductor substrate 10. According to one embodiment of the invention, the semiconductor substrate 10 may be a silicon substrate and the photo-sensing elements may comprise a photodiode, but not limited thereto.

Subsequently, at least one dielectric layer 20 is formed on the semiconductor substrate 10. According to one embodiment of the invention, the dielectric layer 20 may comprise single- or multi-layer dielectric material, for example, silicon dioxide, silicon nitride, etc. The dielectric layer 20 has a top surface 20a such as a silicon dioxide top surface or a silicon nitride top surface. It is to be understood that at least one layer of metal interconnection structure (not shown) may be disposed within the dielectric layer 20.

Subsequently, a lithographic process and an etching process are carried out to form a plurality of lightpipe openings 22 corresponding to the semiconductor elements 102 in the pixel array region 110. The lightpipe openings 22 extend through the entire thickness of the dielectric layer 20 and reveal the surfaces of the semiconductor elements (i.e. photo-sensing elements) 102. It is noteworthy that the aforesaid lightpipe openings are not formed within the peripheral region 120.

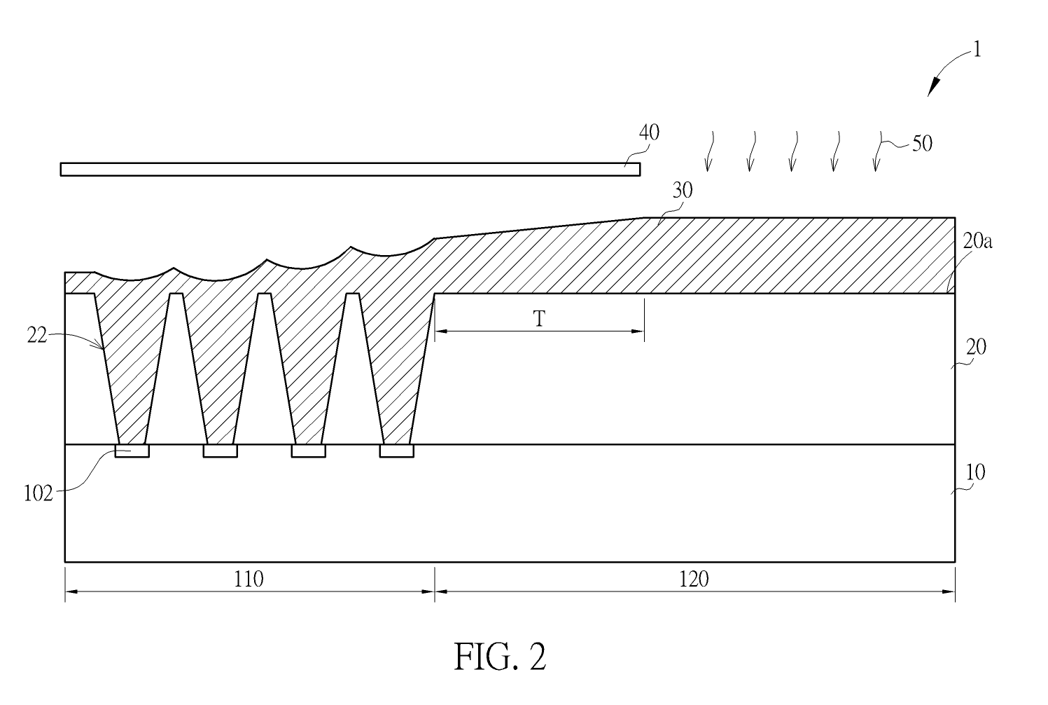

As shown in FIG. 2, a lightpipe material layer 30 is coated on the semiconductor substrate 10 by using a spin-coating method. The lightpipe openings 22 are completely filled with the lightpipe material layer 30. According to one embodiment of the invention, prior to the coating of the lightpipe material layer 30, a liner such as a silicon nitride liner may be formed conformally on the semiconductor substrate 10.

As previously mentioned, after the spin-coating, the poor surface evenness results in thickness variation of the lightpipes in the pixel array region.

The present invention addresses this problem by using a photosensitive polymeric material as the lightpipe material layer 30, which has a high refractive index (n=1.7˜1.9) and a low extinction coefficient (k˜0) in the visible light range.

After spin-coating the lightpipe material layer 30, optionally, a pre-bake process may be performed.

The lightpipe material layer 30 is then subjected to an exposure process 50. A pre-determined photomask 40 is used such that the lightpipe material layer 30 within a pre-determined region within the peripheral region 120 is exposed to a pre-selected light source such as i-line, while the lightpipe material layer 30 within the pixel array region 110 and the transition region T is not exposed to the light source. The aforesaid transition region T may has a dimension of 0˜100 micrometers.

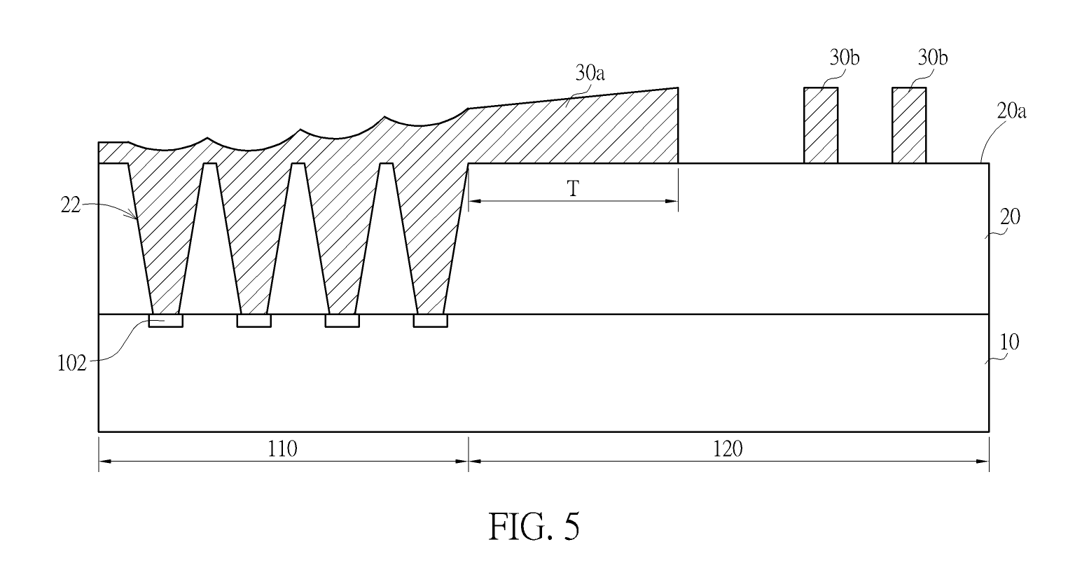

After the aforesaid exposure process 50 is completed, a development process is performed to remove the exposed lightpipe material layer 30 from the region that was exposed to the pre-selected light source during the exposure process 50, thereby revealing a portion of the top surface 20a of the dielectric layer 20 and forming a lightpipe material pattern 30a. According to another embodiment of the invention, the pattern of the photomask may be adjusted such that after the development process a predetermined dummy pattern 30b may be formed within the peripheral region 120, as shown in FIG. 5.

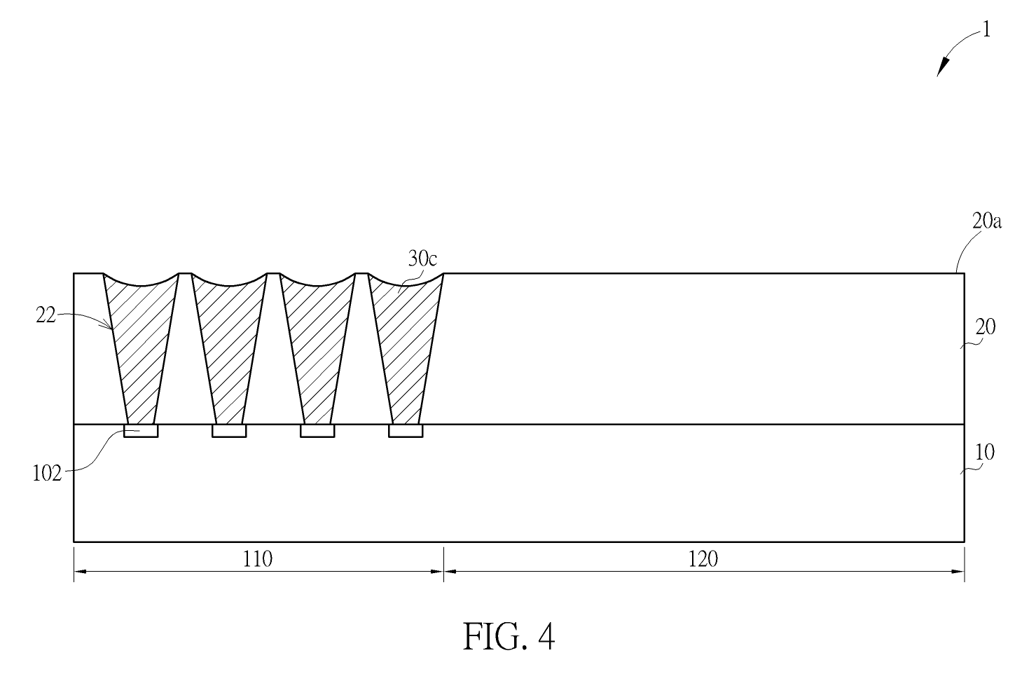

After the aforesaid development process is completed, a chemical mechanical polish (CMP) process 60 is performed. The lightpipe material pattern 30a on the top surface 20a of the dielectric layer 20 is polished away, thereby forming the lightpipes 30c within the lightpipe openings 22, as shown in FIG. 4. According to the embodiment of the invention, an over-polish process may be carried out to ensure the upper ends of the lightpipes 30c within the lightpipe openings 22 are separated from one another and may be further slightly recessed into the lightpipe openings 22.

Thereafter, a color filter film forming process and a microlens process may be performed to form a color filter array layer and a microlens layer (not shown) on the planarized semiconductor substrate 10 and the back-end-of-line of CMOS sensor device 1 is completed. Since the color filter film forming process and a microlens process are well known in the art, the details thereof is therefore omitted.

Those skilled in the art will readily observe that numerous modifications and alterations of the device and method may be made while retaining the teachings of the invention. Accordingly, the above disclosure should be construed as limited only by the metes and bounds of the appended claims.

1. A semiconductor fabrication method, comprising:
providing a semiconductor substrate having thereon a plurality of semiconductor elements;
forming a dielectric layer on the semiconductor substrate;
forming a plurality of openings in the dielectric layer to respectively reveal the plurality of semiconductor elements;
coating a material layer on the semiconductor substrate, wherein the material layer fills into the plurality of openings;
subjecting the material layer to an exposure process and a development process to remove a portion of the material layer, thereby exposing a portion of a top surface of the dielectric layer and simultaneously forming a material pattern and a dummy pattern; and
subjecting the material pattern and the dummy pattern to a chemical mechanical polishing process.

2. The semiconductor fabrication method according to claim 1, wherein the semiconductor substrate comprises a silicon substrate.

3. The semiconductor fabrication method according to claim 1, wherein the semiconductor elements comprise a photo-sensing element.

4. The semiconductor fabrication method according to claim 3, wherein the photo-sensing element comprises a photodiode.

5. The semiconductor fabrication method according to claim 1, wherein the dielectric layer comprises single- or multi-layer dielectric material.

6. The semiconductor fabrication method according to claim 5, wherein the dielectric layer comprises silicon dioxide or silicon nitride.

7. The semiconductor fabrication method according to claim 1, wherein the material layer is a photosensitive polymeric material having a high refractive index (n=1.7˜1.9) and a low extinction coefficient (k˜0) in the visible light range.

8. The semiconductor fabrication method according to claim 1, wherein the openings are lightpipe openings, wherein after subjecting the material pattern to the chemical mechanical polishing process, forming a lightpipe within each of the lightpipe openings.

9. The semiconductor fabrication method according to claim 1, wherein the semiconductor substrate comprises a pixel array region and a peripheral region, and the material pattern and the dummy pattern are respectively formed on the top surface of the dielectric layer in the pixel array region and in the peripheral region.
